(19) United States
(12) Patent Application Publication
(10) Pub. No.: US 2025/0299983 A1
(43) Pub. Date: Sep. 25, 2025

(54) CERAMIC HEATER ASSEMBLY WITH INTERNAL AND EXTERNAL HEATING FUNCTIONALITY USEFUL IN THE FABRICATION OF MICROELECTRONIC DEVICES

(71) Applicant: Tokyo Electron Limited, Tokyo (JP)

(72) Inventor: Melvin Verbaas, Austin, TX (US)

(21) Appl. No.: 18/609,603

(22) Filed: Mar. 19, 2024

(51) Int. Cl. H01L 21/67; C23C 16/46; H01L 21/687

(52) U.S. Cl. CPC H01L 21/67103; H01L 21/67248; H01L 21/68757; C23C 16/46

(57) ABSTRACT

The present invention provides a ceramic heater assembly with internal and external heating functionality. The internal heating functionality includes heater elements embedded in a heated platen as well as a backside heater deployed to deliver heat from the backside to the center region of the platen. The embedded heater elements and the backside heater cooperatively deliver thermal energy to the center region. The present invention improves an ability to heat and control temperature in the central region of a workpiece being processed.

### FIELD OF THE INVENTION

This disclosure relates to microelectronic processing apparatuses and methods that incorporate heated, ceramic support assemblies for supporting and heating a microelectronic workpiece during heated processing in the fabrication of microelectronic devices, and more particularly to such apparatuses and methods in which the heated, ceramic support assemblies include a heated platen supported on a pedestal.

### BACKGROUND OF THE INVENTION

In the semiconductor manufacturing industry, ceramic heaters play an important role in the thermal management of microelectronic workpieces during high-temperature processing operations such as Chemical Vapor Deposition (CVD), Plasma Enhanced Chemical Vapor Deposition (PECVD), and other high temperature processes discussed below. These heaters are specifically designed to support and heat semiconductor wafers to the requisite temperatures that facilitate the deposition of thin films and other materials onto the wafer surface. Made from high-performance ceramic materials such as aluminum nitride (AlN), silicon carbide (SiC), silicon nitride (Si₃N₄), and others, these heaters offer exceptional thermal conductivity, resistance to thermal shock, and chemical stability under the extreme conditions typical of semiconductor processing environments.

The adoption of ceramic heaters in semiconductor fabrication is largely due to their compatibility with the high-temperature requirements of processes like CVD and PECVD. These processes demand excellent temperature control and uniform heat distribution across the wafer surface to ensure the consistent quality and characteristics of the deposited layers. Ceramic heaters, with their high thermal conductivity and stability, are ideally suited to meet these requirements, providing the necessary environment for controlled film growth and material properties.

In many conventional ceramic heater designs, heating elements are incorporated into the platen—the component of the heater that directly supports the wafer—to provide the required heating functionality. These elements are typically arranged in a pattern around the platen periphery or in designated zones to achieve an even distribution of heat. This configuration helps to maintain the temperature uniformity across the wafer surface during processing.

A significant limitation of the conventional ceramic heater design is the formation of a cold spot at the center of the platen. In other words, the central region of the platen is inadequately heated compared to heating zones that are further out from the platen center. This issue arises because the central region of the platen has been reserved for electrical contacts, leaving insufficient space for embedding centrally located heating elements. Without direct heating elements in this central area, there is a notable drop in temperature, leading to a non-uniform temperature profile across the wafer. This cold spot can adversely affect the processing quality, resulting in inconsistent film deposition, material properties, and potentially compromising the performance of the manufactured semiconductor devices.

The industry has attempted to uncover technical solutions that could avoid the cold spot problem for many years. For example, U.S. Pat. No. 11,343,879 issued from a U.S. provisional patent application first filed over six years ago, at which time the cold spot problem already was well known. U.S. Pat. No. 11,343,879 recognizes that cold spot in the center region of a platen is a problem attributed to the presence of the electric terminations in the center region of the platen. Rather than attempt to solve the problem with a new heating strategy to heat the center region, U.S. Pat. No. 11,343,879 instead proposes a strategy to deploy the electrical connection components in a manner that reduces the size of the center region taken up by these components which, in turn, reduces the size of the associated cold spot. The cold spot and its adverse impact on processing quality still remains with this strategy.

The existence of a cold spot in conventional ceramic heater designs underscores a critical challenge in achieving optimal thermal uniformity during semiconductor wafer processing. This issue highlights the need for innovative solutions that can provide comprehensive and uniform heating across the entire surface of the platen, including the central region, without compromising the functionality and performance of the heater. The development of such improved ceramic heaters is essential for advancing semiconductor manufacturing technologies, ensuring the production of high-quality devices that meet the evolving demands of the industry.

### SUMMARY OF THE INVENTION

The present invention provides strategies useful to overcome wafer center cold spots during heated processing of workpieces in the fabrication of microelectronic devices. The technical solution of the present invention is based at least in part upon providing a ceramic heater assembly with internal and external heating functionality. The internal heating functionality includes heater elements that are embedded in a heated platen as well as a backside heater deployed to deliver heat from the backside to the center region of the platen. The embedded heater elements and the backside heater cooperatively deliver thermal energy to the center region. The technical solution of the present invention improves ability to heat and control temperature in the central region of a workpiece being processed.

In one aspect, the present invention relates to an apparatus useful to subject a microelectronic workpiece to a process The apparatus comprises a housing defining a process chamber and a heated workpiece support module. The heated workpiece module comprises a platen positioned in the process chamber. The platen comprises a top surface over which the workpiece is supported during the process; a backside surface; a platen body interposed between the top surface and the backside surface; and a bore formed in a central region of the platen body, wherein the bore has a bore inlet on the backside surface of the heated platen. The apparatus further comprises a first heater comprising a controllable heat source that is at least partially housed in the bore, wherein actuation of the first heater causes the heat source to output thermal energy that is transferred from the heat source to a central region of the platen in a manner effective to controllably heat the central region of the platen and a central region of the microelectronic workpiece when the microelectronic workpiece is supported on the platen. The apparatus comprises one or more controllable heating elements embedded inside the platen body, wherein actuation of each heating element of the one or more controllable heating elements causes each of the one or more controllable heating elements to deliver thermal energy to at least one associated heating zone of the platen, and wherein at least one of the one or more controllable heating elements has an inner boundary proximal to an adjacent portion of the central region of the platen such that said at least one controllable heating element and the first heater independently and cooperatively heat the adjacent portion of the central region when the first heater and said at least one controllable heating element are actuated.

In another aspect, the present invention relates to a heated workpiece support module useful to support a microelectronic workpiece during a process. The workpiece support module comprises a platen positioned in the process chamber. The platen comprises a top surface over which the workpiece is supported during the process; a backside surface; a platen body interposed between the top surface and the backside surface; and a bore formed in a central region of the platen body, wherein the bore has a bore inlet on the backside surface of the heated platen. The heated workpiece module a first heater comprising a controllable heat source that is at least partially housed in the bore, wherein actuation of the first heater causes the heat source to output thermal energy that is transferred from the heat source to a central region of the platen in a manner effective to controllably heat the central region of the platen and a central region of the microelectronic workpiece when the microelectronic workpiece is supported on the platen. The workpiece support module comprises one or more controllable heating elements embedded inside the platen body, wherein actuation of each heating element of the one or more controllable heating elements causes each of the one or more controllable heating elements to deliver thermal energy to at least one associated heating zone of the platen, and wherein at least one of the one or more controllable heating elements has an inner boundary proximal to an adjacent portion of the central region of the platen such that said at least one controllable heating element and the first heater independently and cooperatively heat the adjacent portion of the central region when the first heater and said at least one controllable heating element are actuated.

In another aspect, the present invention relates to a method of processing a microelectronic workpiece. The method comprises the steps of:
a) supporting the microelectronic workpiece on the platen of the heated workpiece support module of the apparatus of claim 1;
b) while the microelectronic workpiece is supported on the platen, subjecting the microelectronic workpiece to a process; and
c) during at least a portion of the process, using the first heater and the one or more controllable heating elements of the heated workpiece support module of the apparatus of claim 1 to heat a central region of the microelectronic workpiece.

### BRIEF DESCRIPTION OF THE DRAWINGS

FIG. 1 schematically shows an illustrative microelectronic processing apparatus incorporating principles of the present invention.

FIG. 2 shows a schematic side view of a heated workpiece support module used in the apparatus of FIG. 1, wherein the heated workpiece support module incorporates principles of the present invention.

FIG. 3 shows a top schematic view of the platen used in the heated workpiece support module of FIG. 2, wherein the central region, centrally located electric terminals, embedded heater elements, and footprint of the backside heater are shown.

FIG. 4 schematically shows a side cross-section view of the heated workpiece support module of FIG. 2, wherein the embedded heater elements and associated electrical connections in the center region as well as the backside deployment of further heater functionality are shown.

FIG. 5 schematically shows a close up view of a portion of FIG. 4, wherein the deployment of the backside heater functionality in a blind bore on the backside of the platen optionally with a gap is shown.

FIG. 6 shows a schematic top view of the platen of FIG. 3 incorporating an alternative deployment of embedded heater elements and a through bore to help house a heat source of a backside heater, wherein the alternative deployment includes an internal array of embedded heater elements and an outer array of embedded heater elements.

FIG. 7 schematically shows a side cross-section view of the heated workpiece support module of FIG. 2 that incorporates the platen of FIG. 6 (having a through bore) as an alternative to the platen of FIG. 3 (that includes a blind bore).

FIG. 8 schematically shows a close up view of a portion of FIG. 7, wherein the deployment of the backside heater functionality in a through bore of the platen optionally with gaps is shown.

FIG. 9 shows an alternative embodiment of the platen of FIG. 3 in which the platen includes a trio of backside heaters, schematically represented by a trio of heater footprints.

### DETAILED DESCRIPTION

The present invention will now be further described with reference to the following illustrative embodiments. The embodiments of the present invention described below are not intended to be exhaustive or to limit the invention to the precise forms disclosed in the following detailed description. Rather a purpose of the embodiments chosen and described is so that the appreciation and understanding by others skilled in the art of the principles and practices of the present invention can be facilitated.

The present invention provides apparatus embodiments and associated methods for performing one or more processes on microelectronic workpieces in the research, development, and fabrication of microelectronic devices such as integrated circuits (ICs), MEMS, sensors, and other electronic components. Several high-temperature processes are used to deposit materials with the aim of creating thin films, layers, or structures on semiconductor wafers. The apparatus embodiments and methods of the present invention are particularly applicable for use in conjunction with high temperature processing of semiconductor workpieces such as high temperature deposition processes wherein a microelectronic workpiece being processed is heated to temperatures greater than about 80° C., greater than about 100° C., greater than about 200° C., greater than about 300° C., greater than 400° C., or greater than 550° C., such as from 80° C. to about 800° C., or 100° C. to about 800° C., or 300° C. to about 800° C.

Examples of such processes in which the practice of the present invention is useful include chemical vapor deposition (CVD) and plasma-enhanced chemical vapor deposition (PECVD). Chemical Vapor Deposition (CVD) is a widely used material deposition process in the fabrication of microelectronic devices, thin films, and coatings. This technique involves the chemical reactions of gaseous precursors on or near the surface of a heated substrate, leading to the deposition of a solid material. The basic principle behind CVD is to introduce one or more volatile precursors into a reaction chamber, where these precursors undergo a thermal decomposition, react with each other, or react with the surface of the substrate at elevated temperatures to form a solid material that coats the substrate. CVD can be conducted under a range of pressures, including from atmospheric pressure (APCVD) to reduced pressures (LPCVD). The choice of process conditions, including temperature, pressure, and types of precursors, influences the properties of the deposited film, such as its composition, purity, morphology, and adhesion to the substrate.

CVD is versatile in terms of the materials it can deposit, including metals, semiconductors, dielectrics, and polymers. It is favored for its ability to produce high-quality, uniform films over large areas and complex shapes. The process is useful in various applications, such as where it is used to deposit gate oxides, insulating layers, conductive films, and various other structural layers of integrated circuits or other microelectronic devices.

Plasma Enhanced Chemical Vapor Deposition (PECVD) is a variation of Chemical Vapor Deposition (CVD). PECVD uses plasma to enhance the chemical reaction rates of the gaseous precursors, sometimes at lower temperatures compared to conventional CVD methods. In PECVD, the substrate on which the film is to be deposited is placed inside a reaction chamber, and gases are introduced. A plasma is then generated in the chamber using RF (radio frequency) power, microwave power, or other plasma sources. The energetic ions and radicals generated in the plasma enable the chemical reactions that lead to the deposition of the solid material onto the substrate.

One advantage of PECVD over traditional CVD is its ability to deposit various types of films at lower temperatures, such as from about 100° C. to about 350° C., although higher temperatures may be used. The lower temperature processing may be beneficial for applications involving temperature-sensitive substrates, such as plastic films or previously deposited layers that might degrade or diffuse at higher temperatures.

Like CVD generally, PECVD is widely used in the fabrication of microelectronic and optoelectronic devices for depositing thin films such as silicon oxide, silicon nitride, amorphous silicon, and various organic and inorganic materials. The films deposited by PECVD are used for a variety of purposes, including dielectric layers, passivation layers, insulating barriers, and anti-reflective coatings, among others. PECVD offers good uniformity, conformal coating over complex geometries, and the ability to precisely control the composition and properties of the deposited films.

In addition to CVD and PECVD, the following are additional high-temperature deposition processes in which the practice of the present invention is useful:

Atomic Layer Deposition (ALD) is a vapor phase technique used for thin film growth that relies on the sequential use of a gas phase chemical process. ALD is known for its excellent conformality and control at the atomic scale, allowing for the precise deposition of nanometer-thick films. Although ALD can be performed at lower temperatures compared to traditional CVD, some ALD processes require high temperatures to achieve certain material qualities.

Molecular Beam Epitaxy (MBE) is a high-vacuum process used in applications such as for the epitaxial growth of crystalline layers. MBE allows atoms or molecules to be evaporated from a source and to condense on a substrate, forming thin films. This process often operates at high temperatures to ensure the mobility of adatoms on the substrate surface, enabling the growth of high-purity epitaxial layers.

Metalorganic Chemical Vapor Deposition (MOCVD), similar to CVD, uses metalorganic precursors for the deposition of thin films. MOCVD is widely used in the production of compound semiconductors and is particularly important in the fabrication of light-emitting diodes (LEDs) and semiconductor lasers. High temperatures are used to decompose the metalorganic compounds and to promote film growth on the substrate.

Sputtering, although not always considered a high-temperature process, may involve elevated substrate temperatures to improve film quality. Sputtering is a physical vapor deposition (PVD) process where atoms are ejected from a solid target material and then deposited on a substrate. Heating the substrate during deposition can enhance the mobility of atoms, leading to better film properties.

Thermal Evaporation (TEPVD) is another type of PVD process in which material from a thermal source is evaporated in a vacuum and then deposited on a substrate. The process can involve high temperatures to vaporize the source material, especially for materials with high melting points.

Rapid Thermal Processing (RTP), although often not practiced as a deposition process per se, is a heat treatment technique used to quickly heat and cool substrates. It is often used to anneal or activate dopants after ion implantation, drive in dopants after diffusion processes, or to change the properties of deposited films. High temperatures may be achieved rapidly to minimize unwanted diffusion in other regions of the device.

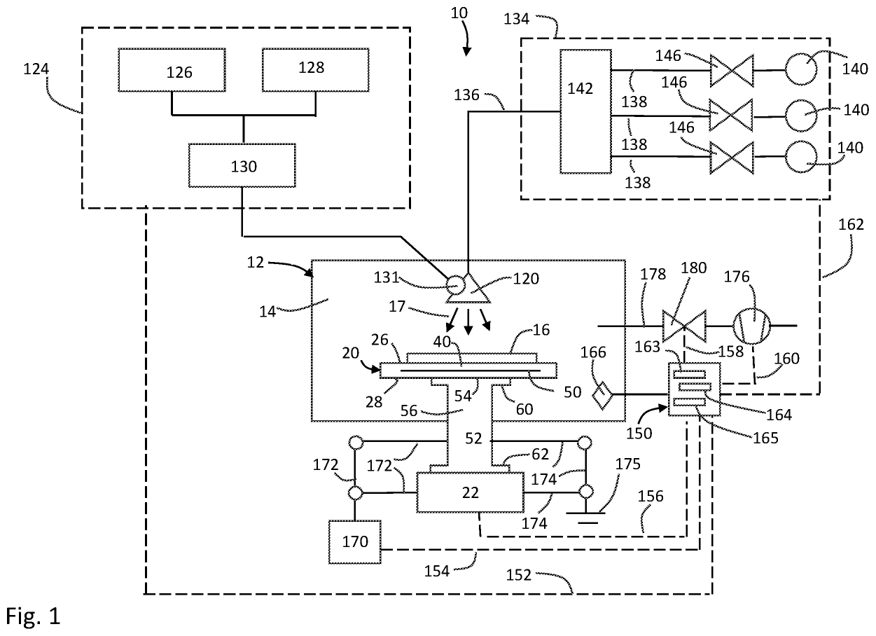

For purposes of illustration, the principles of the present invention will be described with respect to the PECVD apparatus 10 schematically shown in FIGS. 1-4. As seen best in FIG. 1, apparatus 10 includes housing 12 defining process chamber 14 that serves to contain plasma 17 in the process chamber 14. For illustrative purposes, plasma 17 is generated by a capacitor type system including a fluid dispensing unit in the form of showerhead module 120 having an upper RF electrode 131 working in conjunction with a heated workpiece support module 20 having a lower RF electrode 50 therein. Workpiece 16 is supported on the heated workpiece support module 20 during the plasma process.

At least one RF generator system 124 is operable to supply RF energy into a processing zone above an upper surface of workpiece 16 in the process chamber 14 to energize process fluid, e.g., a gas and/or gas clusters, supplied into the processing zone of the process chamber 14 into plasma such that a plasma deposition process may be performed. The process typically is performed under vacuum. Vacuum pump 176 helps to establish a vacuum through vacuum line 178. Vacuum valve 180 helps to control egress of withdrawn vapor, gas, gas clusters, plasma, or other fluids to be evacuated into vacuum line 178.

As an example of an illustrative embodiment, RF generator system 124 includes a high-frequency RF generator 126 and a low-frequency RF generator 128. Each of these may be connected to a matching network 130, which in turn is connected to the upper RF electrode 131 of the showerhead module 120 such that RF energy may be supplied to the processing zone above the workpiece 16 in the process chamber 14.

The power and frequency of RF energy supplied by matching network 130 to the interior of the process chamber 14 is sufficient to generate plasma from the one or more supplied process fluids. In an embodiment both the high-frequency RF generator 126 and the low-frequency RF generator 128 are used. In alternate embodiments, just the high-frequency RF generator 126 is used or only the low-frequency RF generator 128 is used. In an illustrative process, the high-frequency RF generator 126 may be operated at frequencies of about 2-100 MHz; in a preferred embodiment at 13.56 MHz or at about 27 MHz. In illustrative embodiments, the low-frequency RF generator 128 may be operated at about 50 kHz to 2 MHZ; in a preferred embodiment at about 350 to 600 kHz.

The heated workpiece support module includes a platen 24 supported on pedestal 52. The pedestal 52 and platen 24 are coupled together at an interface 54. The platen 20 includes a top or processing side 26 over which the workpiece 16 is supported during processing, a backside 28, and a platen body 38. The top or processing side 26 supports workpiece 16 during processing within the process chamber 14. The platen 24 includes the lower RF electrode 50 therein. The lower RF electrode 50 is preferably grounded during processing such as being coupled to ground contact 175. However, in an alternate embodiment, the lower RF electrode 50 may be supplied with RF energy during processing.

Pedestal 52 includes body 56, upper flange 60, and lower flange 62. Flange 60 is used to help attach pedestal 52 to the backside 28. Flange 62 is used to help attach pedestal 52 to lifting apparatus 22. Lifting apparatus includes components that can be actuated to help raise and lower heated workpiece support module 20. For example, heated workpiece support module 20 may be raised or lowered, as the case may be, to position the platen 24 in a suitable position to load and unload workpiece 16 through a suitable port (not shown). Heated workpiece support module 20 may be raised or lowered to position the workpiece 16 in a suitable position to carry out the desired process. In some instances, the position of heated workpiece support module 20 may be adjusted as a process proceeds. In one illustrative embodiment, lifting apparatus 22 may include a bellows (not shown) that can be expanded or contracted to raise and lower heated workpiece support module 20.

The platen 24 and pedestal 52 of heated workpiece support module 20 are engineered to withstand the rigors of high-temperature processing environments typically encountered in semiconductor fabrication processes such as PVD, CVD, PECVD, APCVD, LPCVD, ALD, MBE, MOCVD, sputtering, TEPVD, RTP, and the like. Given the thermal and mechanical demands placed on the assembly, materials selected for construction exhibit desired thermal conductivity, thermal shock resistance, and chemical stability. Ceramic materials, known for their robust thermal and mechanical properties, are well-suited for this application.

Accordingly, each of platen 24 and pedestal 52 independently comprises one or more ceramic materials. The selection of at least one ceramic as the material of choice for each of the platen 24 and pedestal 52 stems from its ability to maintain structural integrity and performance characteristics at elevated temperatures, which can significantly exceed the threshold levels of conventional materials. Furthermore, ceramics exhibit excellent resistance to corrosion and wear, ensuring longevity and reliability of the wafer support mechanism in a chemically reactive and abrasive processing environment.

Among the ceramics, each of the platen 24 and pedestal 52 preferably is made from aluminum nitride (AlN). Aluminum nitride is preferred material due to its thermal stability as well as its excellent thermal conductivity. The thermal conductivity characteristics help provide efficient transfer of heat to the wafer. This in turn helps to provide uniform temperature distribution across the platen top surface 26 and hence across workpiece 16.

Each of platen 24 and pedestal 52 can be made from one or more other ceramic materials, if desired. Examples of other suitable ceramic materials include one or more of the following: Silicon Carbide (SiC) is known for its high thermal conductivity and excellent mechanical strength. Silicon carbide is also highly resistant to thermal shock, making it suitable for fluctuating temperature conditions. Silicon Nitride (Si₃N₄) offers exceptional thermal stability and resistance to thermal shock, alongside significant mechanical toughness. This makes silicon nitride suitable for demanding processing environments. Boron Nitride (BN) is known for its high thermal conductivity and electrical insulation properties. Boron nitride is particularly useful in applications requiring both thermal management and electrical isolation. Zirconium Dioxide (ZrO₂), or Zirconia exhibits high temperature resistance and thermal insulation properties, along with a low thermal conductivity. This makes zirconia suitable for applications requiring thermal barriers. Alumina (Al₂O₃) provides excellent electrical insulation and resistance to corrosion and wear, making it a versatile choice for various components of the platen 24 and/or pedestal 52.

The fabrication of the ceramic components of heated workpiece support module 20, such as platen 24, pedestal 52, and support member 86 (described below) for use in the context of high-temperature semiconductor processing applications such as CVD and PECVD, preferably involves a manufacturing process known as sintering. This process converts powdered ceramic materials into a solid, dense structure through the application of heat and pressure. A first step in a typical sintering process involves the preparation of the ceramic powder. This powder can be made from a variety of ceramic materials, such as aluminum nitride, silicon carbide, silicon nitride, boron nitride, zirconia, and/or alumina, depending on the desired properties of the final product. The powder may be mixed with a binder or other additives to aid in the sintering process and improve the mechanical properties of the end product.

Once the ceramic powder is prepared, the powder is molded or shaped into the desired form of the component, such as platen 24 or pedestal 52. This shaping can be achieved through various methods, including dry pressing, isostatic pressing, or extrusion. The choice of shaping method depends on the complexity of the component's design and the specific properties required. In dry pressing, the powder is compressed in a rigid mold under high pressure. Isostatic pressing involves applying pressure uniformly in all directions using a fluid medium, which is suitable for achieving high-density and uniform parts. Extrusion, on the other hand, is useful for creating components with constant cross-sectional profiles.

After shaping, the ceramic parts undergo a sintering process. Sintering involves heating the shaped powder in a furnace to a temperature typically below the melting point of the main component but high enough to facilitate diffusion and bonding among the powder particles. This heat treatment causes the particles to bond together, densify, and eliminate porosity, resulting in a solid, dense ceramic component. The sintering atmosphere (which in illustrative modes of practice can be vacuum, inert, or reducing) and the specific temperature profile are carefully controlled to facilitate development of desired material properties and to prevent defects.

Following sintering, the ceramic components optionally may undergo one or more post-sintering treatments to achieve the desired surface finish, dimensional accuracy, or mechanical properties. These treatments can include machining, grinding, polishing, and additional heat treatments. or example, machining or grinding may be required to achieve tight dimensional tolerances or specific surface textures. Additional heat treatments can be used to relieve internal stresses or to modify the microstructure for improved mechanical properties.

To process workpiece 16 in the process chamber 14 of the apparatus 10, one or more process fluids are introduced from a process fluid source 134 into the process chamber 14 via supply line 136 and showerhead module 120. The supplied fluid material is formed into plasma 17 with RF energy such that a film (not shown) may be deposited onto the upper surface of the workpiece 16. In an embodiment, process fluid source 124 includes one or more fluid sources 140. For purposes of illustration, three fluid sources 140 are shown. In some embodiments, only one or two fluid sources 140 may be used. In other embodiments, four or more fluid sources 140 may be used. The fluid material from multiple fluid sources 140 may be supplied to showerhead module 120 singly or in combination. If supplied in combination, multiple fluids may be pre-mixed upstream from showerhead module 120 and dispensed into process chamber 14 as a mixture. Each fluid material can be separately introduced into process chamber 14 in some embodiments. As shown, corresponding supply lines 138 fluidly couple the fluid sources 140 to a manifold 142 to allow pre-mixing upstream from showerhead module 120. Appropriate valving and mass flow control mechanisms schematically shown as valves 146 are used to help ensure that the correct fluid materials in desired amounts are delivered to the showerhead module 120 during workpiece processing.

Power supply 170 is used to supply electrical power to heated workpiece support module 20 and lifting apparatus 22 via electric supply lines 172. Heated workpiece support module 20 and lifting apparatus 22 are coupled to ground contact 175 by electrical grounding lines 174.

For controlling and optimizing Plasma Enhanced Chemical Vapor Deposition (PECVD) processes, a sophisticated control system equipped with various sensors, imaging devices, and measurement tools is essential. This setup allows for real-time monitoring and adjustments to ensure the quality and consistency of the deposited films. Below are types of sensors and devices that can be used in such a system, along with the features they may monitor:

In certain embodiments, a system controller 150 is used to control process implementation and/or monitoring during workpiece loading and unloading, supply monitoring and refill, maintenance, servicing, processing and/or other apparatus operations. The system controller 150 will typically include information harvesting system 166, which may include any of a variety of sensors, imaging devices, measurement devices, and the like deployed at one or more locations around apparatus 10. Controller 150 also may include at least one computer processor 163, at least one interface 164, and at least one memory 165.

Connections to other components of apparatus 10 may be wired and/or wireless. The components may be local and/or remote, such as being cloud-based. For example, system controller 150 communicates with RF generator system 124 via communication pathway 152. System controller 150 communicates with power supply 170 via communication pathway 154. System controller 150 communicates with lifting apparatus 22 via communication pathway 156. System controller 150 communicates with vacuum valve 180 via communication pathway 158. System controller 150 communicates with vacuum pump 176 via communication pathway 160. System controller 150 communicates with process fluid source 134 via communication pathway 162.

The controller 150 may use analog and/or digital communication strategies with respect to the communication pathways 152, 154, 156, 158, 160, and 162. For example, signals for monitoring the process may be harvested and then communicated by information harvesting system 166 by analog and/or digital input communications The signals for controlling the process also may be transmitting using analog and/or digital strategies.

Controller 150 may use information harvesting system 166 to harvest process information from a wide variety of locations within apparatus. Controller 150 can be configured to allow for real-time monitoring and adjustments during apparatus operation. Examples of components including in information harvesting system 166 include one or more of the following: sensors to detect the presence, absence, and position of workpiece 16; sensors to detect the status of each valve, pressure sensors to monitor the pressure inside the PECVD process chamber or supply lines; fluid flow sensors to measure the flow rates of the supplied fluid materials; temperature sensors to monitor the platen, workpiece, supplied fluid materials, and other componentry; plasma diagnostics tools, such as Langmuir probes or optical emission spectroscopy (OES) sensors, to analyze plasma properties (e.g., including density, temperature, and species composition); optical sensors for purposes such as in-situ film thickness measurement and monitoring the uniformity of the film being deposited; mass spectrometers such as to analyze the gas phase reactions and the composition of the plasma; infrared sensors to monitor temperatures such as on the workpiece, platen, and/or the substrate and chamber wall temperatures; humidity sensors such as to measure the moisture level in the chamber; imaging devices, such as high-resolution cameras or scanning electron microscopes (SEM) for surface analysis and defect inspection; electrical property measurement devices such as to assess the electrical properties of the deposited films, such as conductivity, resistivity, or capacitance, using in-situ or ex-situ techniques; sensors to monitor time; sensors to monitor process step initiation, progress, and completion; and/or the like.

Typically, there will be at least one user interface 164 associated with system controller 150. The user interface 164 may include a display screen, graphical software displays of the apparatus and/or process conditions, and user input devices such as pointing devices, keyboards, touch screens, microphones, combinations of these, and the like.

A non-transitory computer machine-readable medium can comprise program instructions for control of the apparatus 10. The computer program code for controlling the processing operations can be written in any conventional computer readable programming language. Compiled object code or script is executed by the processor to perform the tasks identified in the program.

A process may be carried out following a computer executable instructions that cause execution of the process according to a recipe stored in a memory 165 and/or input or selected by a user. Memory 165 may store a plurality of different recipes that are selectable on demand. The user may customize recipe features using interface 164.

For use in processes such as PVD, CVD, PECVD, APCVD, LPCVD, ALD, MBE, MOCVD, sputtering, TEPVD, RTP, and the like, it is highly desirable that the platen 24 that supports a workpiece 16 during a process is heated so that the platen 24 is an important heat source to heat the workpiece 16. Conventional strategies to heat a platen typically embed a plurality of heating elements inside the platen. These heating elements are connected to a source of electrical power. The flowing electricity resistively heats the heating elements. The resulting thermal energy is output by the heating elements to heat the platen and the workpiece.

Unfortunately, many conventional strategies for incorporating embedded heating elements into a platen result in a cold spot in the center region of the platen. This leads to uneven heating of the workpiece, particularly in the colder center. This can impact process uniformity and performance. The cold spot results at least in part because electrical connections to the heater elements are made in the center region of the platen. It has been very challenging to embed heater elements in the center region and still leave enough room in a platen body for the electrical connections that are needed.

For example, U.S. Pat. No. 11,343,879 recognizes that a cold center is a problem. Rather than try to find a way to heat the center region, U.S. Pat. No. 11,343,879 instead proposes an electrical connection strategy that reduces the number of contacts needed and, hence, the size of the cold region in the platen center.

Advantageously, the practice of the present invention provides a strategy to heat the central region of platen 24 and hence the central region of workpiece 16 while supported on the platen 24. As a further advantage, the practice of the present invention leaves enough room in the center region 40 of platen 24 for desired electrical contacts and connections. Using principles of the present invention, a cold center region can be mitigated or even avoided. The result is more uniform heating of the platen 24 and, hence, the workpiece 16.

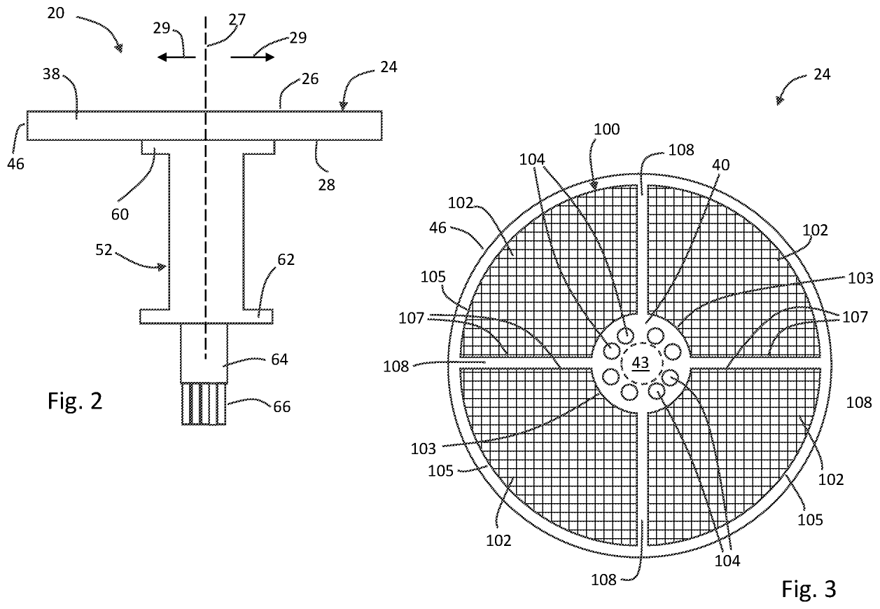

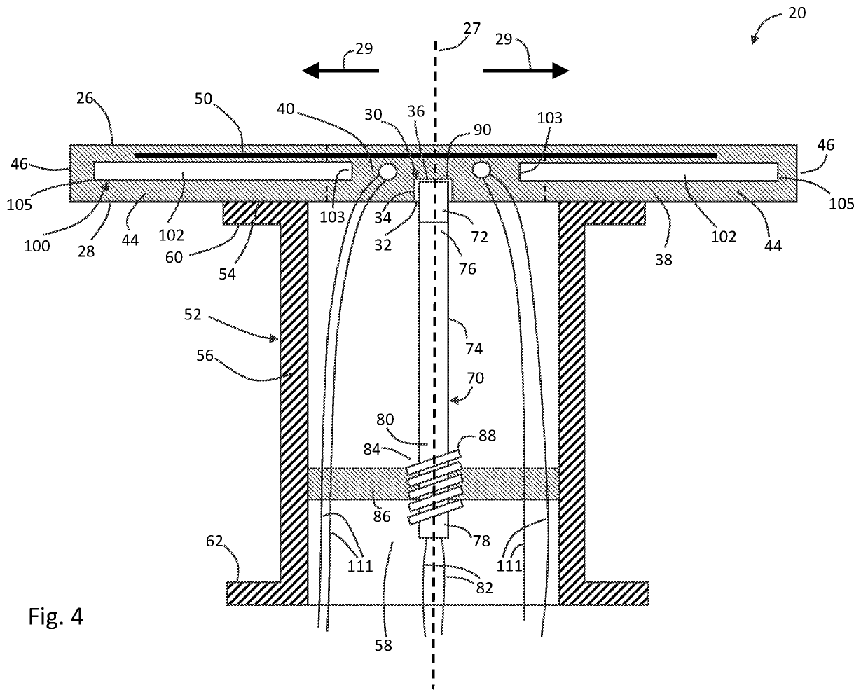

Features and functions of heated workpiece support module 20 according to principles of the present invention are shown in more detail in FIGS. 2 to 4. Referring first to FIG. 4, platen 24 is shown with top surface 26, backside 28, platen body 38, and outer periphery 46. Central axis 27 is shown for reference. The radially outward direction is shown schematically by arrows 29. Thus, for example, outer periphery 47 is radially outward from center axis 27.

Platen 24 includes a centrally located bore 30 formed in platen 24. In this embodiment axis 27 of platen 24 also is the axis of the bore 30. In other embodiments, the axis of bore 30 could be different from axis 27. For example, bore 30 could have an axis that is off-center at some radial distance away from axis 27. As another example, bore 30 could have an axis that is non-parallel to axis 27. As another embodiments, bore 30 could have an axis that is both off-center and non-parallel to axis 27.

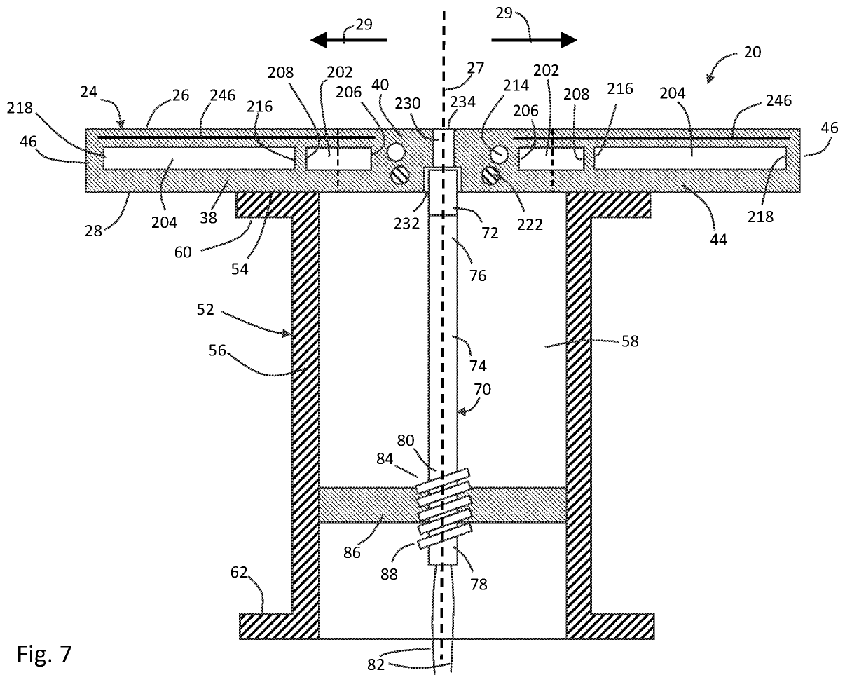

In the practice of the present invention, the bore 30 may be in the form of a blind bore or a through bore. For purposes of illustration, the bore is in the form of a blind bore 30. FIGS. 6 and 7 below illustrate an alternative embodiment of a platen containing a through bore. Blind bore 30 of platen 24 is blind in the sense that blind bore 30 extends only partially through the thickness of platen 24 and is not a through bore. Blind bore 30 includes inlet 32 to provide an egress to blind bore 30 from backside 28. Blind bore 30 in this illustration has a circular geometry and is defined by sidewall 34, inlet 32, and ceiling 36. Blind bore 30 can have other geometries, if desired. In some modes of fabrication, blind bore 30 can be formed by drilling after platen 24 is formed. In some modes of fabrication, blind bore 30 can be molded into platen 24 during the formation of platen 24. In some modes of fabrication, a portion of blind bore 30 is molded and another portion is machined later, such as by drilling to complete the blind bore 30.

As shown best in FIG. 4, pedestal 52 has body 56, upper flange 60, and lower flange 62. Pedestal 52 is hollow and includes interior volume 58 for housing additional components and for providing a conduit for electrical wiring. For purposes of illustration, FIG. 2 schematically shows how wires 64 in a wiring bundle 66 can be fed through pedestal 52 and then connected to other electrical components (not shown in FIG. 2).

Referring again to FIG. 4, and as a first type of heater functionality to help provide center region heating, heated workpiece support module 20 incorporates a first heater in the form of a backside rod heater 70 that is external to platen 24. Even though heater 70 is at least partially positioned inside the interior volume 58 of pedestal 52, heater 70 is external relative to platen 24 in the sense that heater 70 is not embedded and molded inside platen 24. In a further preferred sense, heater 70 is external in that heater 70 is thermally coupled to platen 24 (via insertion into blind bore 30) after platen 24 is formed. Functionally, heater 70 helps to deliver thermal energy to central region 40 of platen 24, and hence, to the central region of workpiece 16 (see FIG. 1) supported on platen 24. In illustrative embodiments, the backside heater 70 outputs thermal energy in a manner effective to controllably heat the central region 40 at a temperature greater than about 80° C., greater than about 100° C., greater than about 200° C., greater than about 300° C., greater than 400° C., or greater than 550° C., such as from 80° C. to about 800° C., or 100° C. to about 800° C., or 300° C. to about 800° C.

Heater 70 is in the form of a rod heater having a tubular body 74 extending from upper end 76 to bottom end 78. As one option, heater 70 can be in the form of a nickel rod heater. Heater 70 includes a controllable heat source in head 72 at upper end 76. The heat source can be controllably actuated to modulate thermal energy delivered from the heat source. Thus, when heating center region 40, the thermal energy output can be reduced if central region 40 is hotter than a desired setpoint temperature or temperature range or increased if central region 40 is cooler than the desired setpoint temperature or temperature range. Wires 82 are used to couple heater 70 to a power supply 170 (see FIG. 1) of electrical power.

In a preferred implementation, the head 72 of heater 70 is not directly mechanically coupled or directly chemically bonded to platen 24. Instead, a lower portion 80 of the tubular body 74 is mounted in a manner so that the head 72 is suspended above a mounting site 84 inside blind bore 30. This allows the head 72 to float inside blind bore 30 to accommodate thermal expansion effects and to avoid locking head 72 and platen 24 together in a way that could create undue mechanical stresses that could cause damage. Depending on the materials used to fabricate platen 24 and the head 72, the materials may differ in terms of thermal expansion. The suspension of head 72 in this manner allows the head 72 to move in any direction to help to avoid such stresses and potential damage.

FIG. 4 shows how lower portion 80 of heater 70 proximal to bottom end 78 is resiliently coupled to support member 86 at mounting site 84. The resilient coupling is shown schematically by spring 88. The resilient coupling allows the heater 70 to move relative to pedestal 52 while the position of head 72 in blind bore 30 is maintained in a manner effective for the heat source in head 72 to be thermally coupled to central region 40.

Advantageously, the diameter of a rod heater across the head 72 can be quite compact, such as in the range from 1 mm to 25 mm. This means that the footprint 43 of the blind bore 30 is a fraction of the total area of the central region 40. In the meantime, the heater 70 can heat an area that is much larger than merely the footprint 43. This leaves a substantial amount of room for electrical connections in the central region 40 while still allowing heater 70 to deliver thermal energy and heat to the central region 40. For example, heater 70 may have a footprint that is sufficiently small such that the central region 40 comprises the footprint 43 and a plurality of electric connections 104 that are electrically coupled to the one or more controllable heating elements 102 embedded inside the platen body.

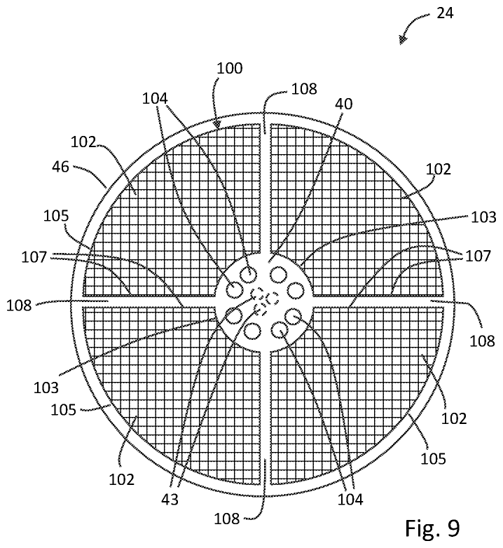

As an option, although a single heater 70 is shown deployed on the backside of platen 24, two or more backside heaters 70 may be deployed in the central region 40. For example, FIG. 9 shows an alternative embodiment of platen 24 that is identical to platen 24 discussed with respect to FIGS. 1-4 except that of heaters 70 are symmetrically deployed in the central region 40. This is shown by the trio of heater footprints 43 shown in FIG. 9.

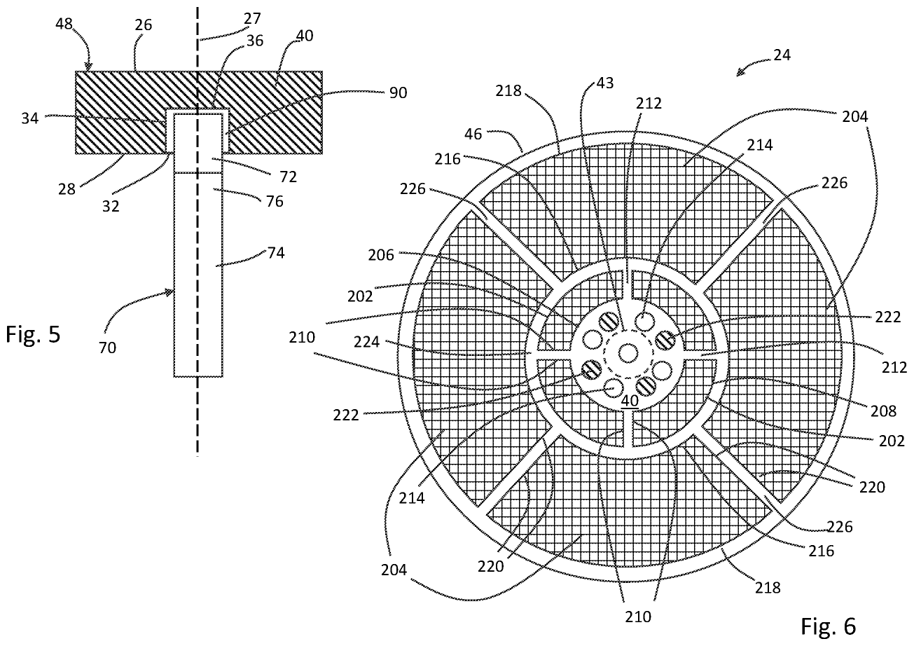

FIG. 5 schematically shows a close up view of head 72 housed in blind bore 30 in a portion 48 of platen 24. Only a portion of platen 24 and heater 70 are shown. FIG. 5 shows an optional deployment in which there is a gap 90 between head 72 and the adjacent sidewall 34 and ceiling 36 of blind bore 30. This gap allows head 72 to float in a suspended fashion inside blind bore 30 without unduly contacting platen 24. This gap strategy helps to reduce stresses that could be transferred between heater 70 and platen 24 due to thermal expansion effects or due to mechanical stresses if head 72 and platen 24 were locked together.

As a second kind of heater functionality, FIGS. 3 and 4 show that workpiece support module 20 includes an array 100 including one or more controllable heater elements 102 embedded inside platen 24. RF electrode 50 is shown as being deployed above the heater elements 102 but can be deployed below the heater elements 102 as an alternative option. Four heater elements 102 are shown for purposes of illustration in FIG. 3. A greater or lesser number of heater elements 102 may be used.

Actuation of each heater element 102, respectively, delivers thermal energy to associated heating zones in outer region 44 of platen 24. Additionally, heater elements 102 and heater 70 cooperatively deliver thermal energy to central region 40. Each heater element 102 is independently controllable to customize the degree of heating in each associated heating zone, and to adjust the amount of thermal energy delivered to the adjacent portion of the central region 40.

As seen best in FIG. 3, each heater element 102 has an inner boundary 103, outer boundary 105, and side boundaries 107. Radial gaps 108 are between adjacent side boundaries 107 of adjacent heater elements 102. Each heating element 102 is electrically coupled to associated electrical contacts 104 by wires (not shown). In other embodiments, a particular electrical contact 104 can be coupled to two or more heater elements 102. Wires 111 electrically couple the contacts 104, and hence heater elements 102, to a source of electrical power such as power supply 170 (see FIG. 1). The footprint 43 of the heater 70 is sufficiently small so that there is plenty of room available in central region 40 for the contacts 104 and wires.

For purposes of the present invention, the central region 40 is defined as the central region of a platen that is radially inward from the innermost boundaries of one or more embedded heater elements that in top plan view surround the center of the platen. This means that the inner boundaries of such heater elements cumulatively define the boundary of the central region but otherwise the heater elements are outside the central region. For example, as applied to the top plan view of FIG. 3, platen 24 includes center region 40 that in this embodiment is the generally circular region defined by the cumulative inner boundaries 103 of the heater elements 102. Outer region 44 is radially outward from center region 40 and extends from the inner boundaries 103 of heater elements 102 to the outer periphery 46 of the platen 24. Thus, except for the innermost boundaries 103 helping to define the center region 40, heater elements 102 are deployed in the outer region 44.

Even though center region 40 generally is substantially devoid of components of heating elements 102 that are primarily intended to deliver process heating, strategies of the present invention still allow center region 40 to be uniformly heated during workpiece processing. Heated workpiece support module 20 of FIGS. 1-4 implements the technical solution of the present invention by using a backside heater 70 and at least one embedded heater element 102 to cooperatively heat the center region 40 of the platen 24. Actuation of the backside heater 70 causes the heat source 72 of heater 70 to output thermal energy that is transferred from the heat source 72 to the central region 40 of the platen 24 in a manner effective to controllably heat the central region 40 of the platen 24, and thus a central region of the microelectronic workpiece 16 (see FIG. 1) when the microelectronic workpiece 16 is supported on the platen 24.

Additionally, actuation of each heating element 102 of the one or more controllable heating elements 102 causes each of the one or more controllable heating elements 102 to deliver thermal energy to at least one associated heating zone of the platen 24. At least one of the one or more controllable heating elements 102 has an inner boundary 103 proximal to an adjacent portion of the central region 40 of the platen 24 such that said at least one controllable heating element 102 and the heater 70 independently and cooperatively heat the adjacent portion of the central region 40 when the heater 70 and said at least one controllable heating element 102 are actuated.

Each of heater elements 102 is independently controllable relative to each other and backside heater 70 to allow the heat delivery to each associated heating zone and the central region 40 to be independently adjusted if too cool or too hot. With heater elements 102 and backside heater 70 being independently controllable, the present invention provides improved strategies for uniformly controlling the temperature over the full area of central region 40.

In sum, both the backside heater 70 and the embedded heater elements 102 having inner boundaries 103 proximal to the central region 40 cooperatively deliver heat to the center region 40. The thermal energy deliveries of heater elements 102 and backside heater 70 to the center region 40 are complementary The backside heater 70 delivers thermal energy more centrally while the embedded heater elements 102 deliver thermal energy to an outer portion of the central region 40. The heat flux of the backside heater 70 is highest in the area of its footprint 43. Less heat flux from heater 70 reaches the more distance portions of central region 40. In other words, the heat flux from the backside heater 70 tends to decrease with increasing radial distance from the footprint 43. Hence, the outer periphery of the central region 40 adjacent to the inner boundaries 103 of the heating elements 102 does not receive as much heat flux from heater 70 as does the portion of central region more proximal to the footprint area 43. Advantageously, the heater elements 102, which are adjacent to the center region 40, can boost the heat flux delivered to the outer portion of the central region 40 to promote more uniform heating of the entire central region 40. Further, backside heater 70 delivers heat to the center region 40 from a relatively small footprint 43, this leaves plenty of room in the center region 40 to provide electrical connections 104 for the embedded heater elements 102. Consequently, the cooperative heat delivery occurs predominantly in the portions of the center region 40 more distant from the heater footprint 43 to provide a heat boost where the heat flux from the backside heater has dissipated to a greater degree.

FIGS. 6 to 8 show an alternative embodiment of a heater element deployment that can be used in platen 24 in place of the heating array 100 of FIGS. 3 to 4. Further, the embodiment of FIGS. 6 to 7 includes a through bore 230 instead of a blind bore 30 as shown in FIGS. 3 to 4. The heater array deployment used in FIG. 6 includes a plurality of controllable heating elements in which a first portion is deployed as an inner, desirably annular array of heater elements 202 proximal to the central region 40 and the centrally located footprint 43 and a second portion is deployed as an outer, desirably annular array of heater elements 204 distal from the central region 40 and the centrally located footprint 43 and proximal to outer periphery 46. Each of heater elements 202 and 204 heats an associated heating zone of platen 24.

Each heater element 202 has an inner boundary 206, an outer boundary 208, and side boundaries 210. Gaps 212 are between adjacent heater elements 202. Electrical contacts 214 in central region 40 couple heater elements 202 to a power supply 170 (see FIG. 1) of electrical power.

Each heater element 204 includes inner boundary 216, outer boundary 218, and sides 220. Gaps 226 are between adjacent heater elements 204. Electrical contacts 222 in central region 40 electrically couple heater elements 204 to a power supply 170 of electrical power. Annular gap 224 is between heater elements 202 and heater elements 204.

In this embodiment, the center region 40 is the generally circular area radially inward from the circular boundary cumulatively defined by the inner boundaries 206 of heater elements 202. Thus, heater elements 202 are radially outward from the central region, and heater elements 204 are even further radially outward, being radially outward being annular gap 224.

In use, backside heater 70 and inner heater elements 202 cooperate to controllably heat central region 40. Inner heater elements 202 also heat associated heating zones in a portion of the outer region 44 between central region boundary 42 and outer periphery 46. Outer heater elements 204 heat associated heating zones in the outer region 44.

In sum, the heater elements 202 and 204 are divided into two kinds of arrays, namely the inner array of heater elements 202 and the outer array of heater elements 204. This would allow even more uniform heating control of platen 24 because now both the backside heater 70 and the heater elements 202 can be independently controlled relative to each other and relatively to the outer heater elements 204 to help tune the heat delivered to center region 40. This can account for the lower heat flux from the backside heater with increasing distance from the center while the ability to independently control the array of heater elements 202 avoids overheating or underheating the middle annular region of the platen 24. In the meantime, the outer heater elements 204 are independently controlled so that heat delivered to a large portion of the outer region 44 can be customized relative to the inner heating zones associated with the heater elements 202.

This allows heat delivery to be tuned and customized in more heating zones of the platen 24. For example, if the zones of platen 40 proximal to central region 40 are too cool, each of the heater elements 202 can be controlled to deliver more heat without as much risk that this would overheat other zones associated with other heater elements 202 or the heater elements 204. In effect, three different classes of heating control are deployed. The very center is controlled by the backside heater 70, the next annular region outward from the center is cooperatively controlled by the backside heater 70 and the heater elements 202, and the third, outermost annular region is controlled with the heater elements 204. Each of heater elements 202 and 204 can be independently controlled relative to other heater elements 202 or 204 and the backside heater 70.

In any embodiments of the invention shown in FIGS. 1-6, a variety of control strategies may be used to help control temperature of the platen 24 and workpiece 16. For example, feedback and/or feedforward strategies using proportional, integral, and/or derivative control, optionally with artificial intelligence functionality, can be used to sense information indicative of temperature and to independently increase or decrease the heat output of any of the backside heater 70, heater elements 102, heater elements 202, and/or heater elements 204. In addition to directly measuring temperature in various heating zones, other characteristics can be monitored and used for temperature control, such as the thickness of the film being deposited. For example, if the thickness is too thin in a heating zone, and if thickness inversely correlates to temperature, the temperature in the zone can be increased. If the thickness is too thick in a heating zone, and if thickness inversely correlates to temperature, the temperature in the zone can be decreased.

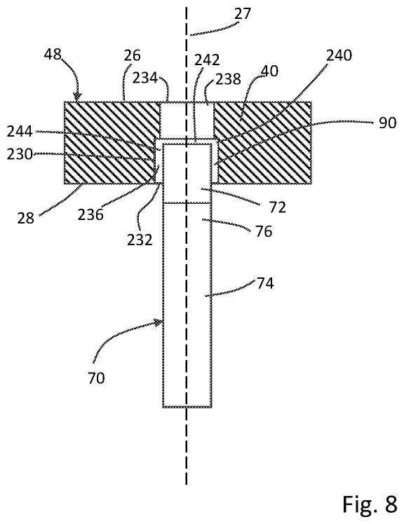

As shown best in the close up view of a portion 48 of platen 24 in FIG. 8, the through bore 230 has an inlet 232 on the backside surface 28 of platen 24 and an inlet 234 on the top surface 26. Proximal to backside surface 28, through bore 230 includes a relatively wider diameter region 236. Proximal to top surface 26, through bore 230 includes a relatively narrower diameter region 238. Shoulder 240 is at the interface between the relatively wider and narrower regions 236 and 238. The through bore 230 may be sized so that there is an upper gap 242 and a lower gap 244 between heater 70 and the adjacent walls of platen 24 that define the through bore 230. Through bore 230 may help to let process chamber gas in behind the platen 24. Platen 24 further includes RF electrode 246.

All patents, patent applications, and publications cited herein are incorporated herein by reference in their respective entities for all purposes. The foregoing detailed description has been given for clarity of understanding only. No unnecessary limitations are to be understood therefrom. Various modifications and alterations of this disclosure will become apparent to those skilled in the art without departing from the scope and principles of this disclosure, and it should be understood that this disclosure is not to be unduly limited to the illustrative embodiments set forth hereinabove.

What is claimed is:

1. An apparatus useful to subject a microelectronic workpiece to a process, said apparatus comprising:
a) a housing defining a process chamber;
b) a heated workpiece support module, comprising:
1) a platen positioned in the process chamber, wherein the platen comprises:
i) a top surface over which the workpiece is supported during the process;
ii) a backside surface;
iii) a platen body interposed between the top surface and the backside surface; and
iv) a bore formed in a central region of the platen body, wherein the bore has a bore inlet on the backside surface of the heated platen;
2) at least a first backside heater comprising a controllable heat source that is at least partially housed in the bore, wherein actuation of the first heater causes the heat source to output thermal energy that is transferred from the heat source to a central region of the platen in a manner effective to controllably heat the central region of the platen and a central region of the microelectronic workpiece when the microelectronic workpiece is supported on the platen; and
3) one or more controllable heating elements embedded inside the platen body, wherein actuation of each heating element of the one or more controllable heating elements causes each of the one or more controllable heating elements to deliver thermal energy to at least one associated heating zone of the platen, and wherein at least one of the one or more controllable heating elements has an inner boundary proximal to an adjacent portion of the central region of the platen such that said at least one controllable heating element and the first heater independently and cooperatively heat the adjacent portion of the central region when the first heater and said at least one controllable heating element are actuated.

2. The apparatus of claim 1, wherein the first heater outputs thermal energy in a manner effective to controllably heat the central region at a temperature in the range from 300° C. to 800° C.

3. The apparatus of claim 1, wherein the first heater outputs thermal energy in a manner effective to controllably heat the central region at a temperature greater than 400° C.

4. The apparatus of claim 1 further comprising a hollow pedestal comprising an interior volume, wherein the platen is supported on the pedestal, and wherein each of the pedestal and the platen independently comprises a ceramic material.

5. The apparatus of claim 4, wherein the pedestal and the platen comprise aluminum nitride.

6. The apparatus of claim 1, wherein the first heater has a footprint that is sufficiently small such that the central region comprises the footprint and a plurality of electric connections that are electrically coupled to the one or more controllable heating elements embedded inside the platen body.

7. The apparatus of claim 1, wherein the bore is a blind bore.

8. The apparatus of claim 1, wherein the bore is a through bore.

9. The apparatus of claim 1, wherein the first heater comprises a tubular body extending from an upper end to a bottom end, wherein the first heater comprises a controllable heat source in a head at the upper end, wherein the head is housed in the bore, and wherein the controllable heat source is thermally coupled to the central region.

10. The apparatus of claim 9, wherein the head is suspended and floats inside the bore.

11. The apparatus of claim 9, wherein a lower portion of the tubular body proximal to the bottom end is resiliently coupled to a mounting site.

12. The apparatus of claim 9, wherein the head has a diameter in the range from 1 mm to 25 mm.

13. The apparatus of claim 9, wherein the bore is a blind bore having a sidewall and a ceiling, and wherein the head is positioned in the bore such that there is a gap between the head and the sidewall and the ceiling.

14. The apparatus of claim 1, further comprising at least one additional backside beater having a footprint in the central region.

15. The apparatus of claim 1, wherein the apparatus comprises a plurality of the controllable heating elements embedded inside the platen body, wherein a first portion of the plurality of the controllable heating elements is deployed in an inner array proximal to the central region, and wherein a second portion of the plurality of controllable heating elements is deployed in an outer array that is distal from the central region.

16. The apparatus of claim 15, wherein there is an annular gap between the inner array and the outer array.

17. The apparatus of claim 15, wherein the first portion of the plurality of the controllable heating elements are cooperatively deployment with the first heater in a manner effective to controllably heat the central region.

18. The apparatus of claim 9, wherein the bore is a through bore comprising a relatively wider region proximal to the backside surface and a relatively narrower region proximal to the top surface, and wherein the head is housed in the relatively wider region.

19. A heated workpiece support module useful to support a microelectronic workpiece during a process, said workpiece support module comprising:
a) a platen positioned in the process chamber, wherein the platen comprises:
1) a top surface over which the workpiece is supported during the process;
2) a backside surface;
3) a platen body interposed between the top surface and the backside surface; and
4) a bore formed in a central region of the platen body, wherein the bore has a bore inlet on the backside surface of the heated platen;
b) a first heater comprising a controllable heat source that is at least partially housed in the bore, wherein actuation of the first heater causes the heat source to output thermal energy that is transferred from the heat source to a central region of the platen in a manner effective to controllably heat the central region of the platen and a central region of the microelectronic workpiece when the microelectronic workpiece is supported on the platen; and
c) one or more controllable heating elements embedded inside the platen body, wherein actuation of each heating element of the one or more controllable heating elements causes each of the one or more controllable heating elements to deliver thermal energy to at least one associated heating zone of the platen, and wherein at least one of the one or more controllable heating elements has an inner boundary proximal to an adjacent portion of the central region of the platen such that said at least one controllable heating element and the first heater independently and cooperatively heat the adjacent portion of the central region when the first heater and said at least one controllable heating element are actuated.

20. A method of processing a microelectronic workpiece, comprising the steps of:
a) supporting the microelectronic workpiece on the platen of the heated workpiece support module of the apparatus of claim 1;
b) while the microelectronic workpiece is supported on the platen, subjecting the microelectronic workpiece to a process; and
c) during at least a portion of the process, using the first heater and the one or more controllable heating elements of the heated workpiece support module of the apparatus of claim 1 to heat a central region of the microelectronic workpiece.
